(19) United States
(12) Patent Application Publication
(10) Pub. No.: US 2021/0056870 A1
(43) Pub. Date: Feb. 25, 2021

(54) COVER SHEET AND FLEXIBLE DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Feng XU, Wuhan, Hubei (CN)

(21) Appl. No.: 16/641,342

(22) PCT Filed: Dec. 9, 2019
(86) PCT No.: PCT/CN2019/123946

§ 371 Date: Feb. 24, 2020

(30) Foreign Application Priority Data
Aug. 23, 2019 (CN) 201910782716.4

(51) Int. Cl. G09F 9/30; H01L 27/32; G06F 1/16

(52) U.S. Cl. CPC G09F 9/301; G06F 1/1656; G06F 1/1652; H01L 27/323

(57) ABSTRACT

A cover sheet and a flexible display device are provided. The cover sheet has at least one first bending region. A photoresponsive polymer layer is disposed in the first bending region of the cover sheet. Material composition of the photoresponsive polymer layer includes a photoresponsive polymer. The photoresponsive polymer is either a rigid polymer under a first illuminating condition or a flexible polymer under a second illuminating condition.

### BACKGROUND OF DISCLOSURE

### 1. Field of Disclosure

The present disclosure relates to the field of display technology, and more particularly, to a cover sheet and a flexible display device.

### 2. Description of Related Art

Flexible display devices need to have good bendability in order to ensure that they are bendable when being bent. Also, the flexible display devices need to have certain mechanical strength, so that they are prevented from being damaged in the course of repeated use. Currently, when protective cover sheets are used as protective layers of the flexible display devices, a part of the protective cover sheets corresponding to a bending region of the flexible display devices needs to have good flexibility when the flexible display devices are bent, and to have enough mechanical strength when the flexible display devices are opened.

Therefore, it is necessary to provide a technical solution to solve the problem that a part of the protective cover sheets corresponding to a bending region of the flexible display devices cannot have bendability and mechanical performance both when conventional protective cover sheets are used in the flexible display devices.

### SUMMARY

A technical problem is that, the present disclosure aims to provide a cover sheet and a flexible display device, wherein a part of the cover sheet corresponding to a bending region of the flexible display device has good flexibility when the flexible display device is folded, and has good mechanical performance when the flexible display device is opened.

A technical solution is that, the present disclosure provides a cover sheet having at least one first bending region, the cover sheet including a photoresponsive polymer layer disposed in the at least one first bending region of the cover sheet, wherein material composition of the photoresponsive polymer layer includes a photoresponsive polymer, and wherein the photoresponsive polymer is either a rigid polymer under a first illuminating condition or a flexible polymer under a second illuminating condition.

In the above cover sheet, two first non-bending regions are disposed on two opposite sides of each of the at least one first bending region respectively.

In the above cover sheet, the photoresponsive polymer layer extends from the at least one first bending region to the first non-bending regions.

The above cover sheet further includes a hard layer disposed in the non-bending regions and on a surface of the photoresponsive polymer layer.

In the above cover sheet, the first illuminating condition includes a surrounding light illumination and/or an ultraviolet illumination; and the second illuminating condition includes one of a red-light illumination, a blue-light illumination, a green-light illumination, and a lightless illumination, and intensity of the red-light illumination, the blue-light illumination, and the green-light illumination is greater than that of red light, blue light, and green light of the surrounding light illumination.

In the above cover sheet, the photoresponsive polymer is selected from an azo polymer or an azo derivative polymer.

In the above cover sheet, the photoresponsive polymer is an aromatic azo polymer.

In the above cover sheet, the photoresponsive polymer has a transitional relaxation time of less than 1 second.

In the above cover sheet, the transitional relaxation time of the photoresponsive polymer is less than 0.5 second.

The present disclosure provides a flexible display device, including a cover sheet and a flexible display panel, wherein the cover sheet is disposed on a light-emitting side of the flexible display panel;

wherein the cover sheet has at least one first bending region and includes a photoresponsive polymer layer disposed in the at least one first bending region of the cover sheet, material composition of the photoresponsive polymer layer includes a photoresponsive polymer, and the photoresponsive polymer is either a rigid polymer under a first illuminating condition or a flexible polymer under a second illuminating condition; and

wherein the flexible display panel has at least one second bending region respectively corresponding to the at least one first bending region.

In the above flexible display device, two first non-bending regions are disposed on two opposite sides of each of the at least one first bending region respectively.

In the above flexible display device, the photoresponsive polymer layer extends from the at least one first bending region to the first non-bending regions.

In the above flexible display device, the cover sheet further includes a hard layer disposed in the non-bending regions and on a surface of the photoresponsive polymer layer.

In the above flexible display device, the first illuminating condition includes a surrounding light illumination and/or an ultraviolet illumination; and the second illuminating condition includes one of a red-light illumination, a blue-light illumination, a green-light illumination, and a lightless illumination, and intensity of the red-light illumination, the blue-light illumination, and the green-light illumination is greater than that of red light, blue light, and green light of the surrounding light illumination.

In the above flexible display device, the red-light illumination, the blue-light illumination, and the green-light illumination are provided by the flexible display panel.

In the above flexible display device, the photoresponsive polymer is selected from an azo polymer or an azo derivative polymer.

In the above flexible display device, the photoresponsive polymer is an aromatic azo polymer.

In the above flexible display device, the photoresponsive polymer has a transitional relaxation time of less than 1 second.

The above flexible display device further includes a touch layer disposed between the cover sheet and the flexible display panel.

The beneficial effect of the present disclosure is that, a cover sheet and a flexible display device are provided, wherein a cover sheet has at least one first bending region and includes a photoresponsive polymer layer disposed in at least one first bending region of the cover sheet, material composition of the photoresponsive polymer layer includes a photoresponsive polymer, and the photoresponsive polymer is either a rigid polymer under a first illuminating condition or a flexible polymer under a second illuminating condition, causing a part of the cover sheet corresponding to a bending region of the flexible display device to have good flexibility when the flexible display device is bent, and to have good mechanical performance when the flexible display device is opened. Thus, protection is achieved.

### BRIEF DESCRIPTION OF DRAWINGS

FIG. 1 is a schematic structural diagram of a flexible display device according to a first embodiment of the present disclosure.

FIG. 2 is a schematic structural diagram of a cover sheet of the flexible display device as shown in FIG. 1.

FIG. 3 is a schematic diagram of transition of a photoresponsive polymer under a first illuminating condition and under a second illuminating condition.

FIG. 4 is a schematic structural diagram of a flexible display device according to a second embodiment of the present disclosure.

### DETAILED DESCRIPTION OF EMBODIMENTS

For the embodiments of the present disclosure, their technical solutions will be described clearly and completely in conjunction with their accompanying drawings below. It is obvious that the embodiments described herein are merely a part of the embodiments of the present disclosure instead of all of the embodiments. A person having ordinary skill in this field can obtain other embodiments according to the embodiments of the present disclosure under the premise of not paying creative works, and all of these embodiments should be within the protective scope of the present disclosure.

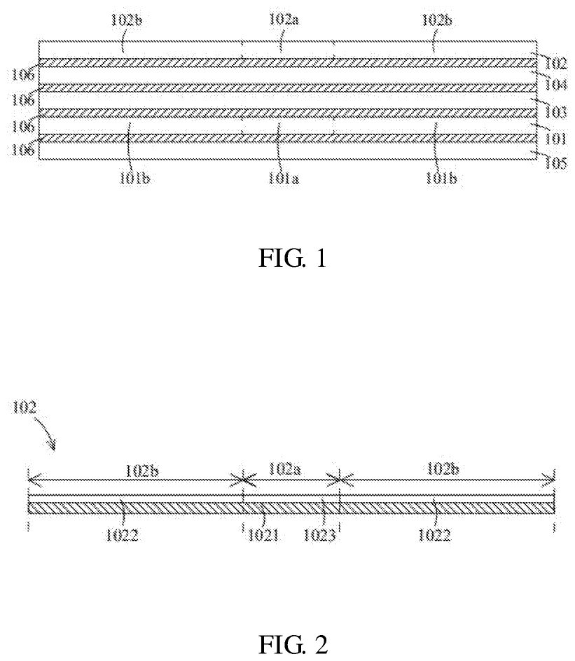

Please refer to FIGS. 1-2, FIG. 1 is a schematic structural diagram of a flexible display device according to a first embodiment of the present disclosure, and FIG. 2 is a schematic structural diagram of a cover sheet of the flexible display device as shown in FIG. 1. The flexible display device is an inward-bent flexible display device. The flexible display device includes a flexible display panel 101, a cover sheet 102, a touch layer 103, a polarizing sheet 104, and a rear cover sheet 105.

The flexible display panel 101 is used to display images. The flexible display panel 101 is a flexible organic light-emitting diode display panel. The flexible display panel 101 can be a top-emission organic light-emitting diode display panel and can also be a bottom-emission organic light-emitting diode display panel. Because of good flexibility, the flexible display panel 101 can be transferred to be in a bending state or a flexible state.

The flexible display panel 101 has at least one second bending region 101a, causing it to be switched to be in a bending state or an opened state, so that the demand for foldability of the flexible display panel 101 in the flexible display device is satisfied. The flexible display panel 101 further has several second non-bending regions 101b. Two second non-bending regions 101b are disposed on two opposite sides of each of the second bending regions 101a respectively. Both at least one second bending region 101a and the second non-bending regions 101b of the flexible display panel 101 display images. Specifically, as shown in FIG. 1, the flexible display panel 101 has a second bending region 101a. Two second non-bending regions 101b are disposed on two opposite sides of the second bending region 101a respectively. Two second non-bending regions 101b are symmetrically disposed on two sides of the second bending region 101a.

The flexible display panel 101 includes a flexible substrate and an organic light-emitting diode array layer disposed on the flexible substrate. The organic light-emitting diode array layer includes several organic light-emitting diodes arranged in an array. The organic light-emitting diodes include red organic light-emitting diodes, blue organic light-emitting diodes, and green organic light-emitting diodes. Each organic light-emitting diode includes a cathode, an anode, and an organic light-emitting layer disposed between the cathode and the anode. The flexible display panel 101 can further include a thin-film transistor array layer. The thin-film transistor array layer includes several thin-film transistors arranged in an array. The thin-film transistors are used to control the organic light-emitting diodes to illuminate.

The cover sheet 102 is used to protect the flexible display panel 101. The cover sheet 102 is disposed on a light-emitting side of the flexible display panel 101. The thickness of the cover sheet 102 is set between 40 and 200 nanometers. For example, the thickness of the cover sheet 102 is 50, 80, or 120 nanometers, etc. The cover sheet 102 has at least one first bending region 102a, causing it to be switched to be in a folded state or an opened state, so that the demand for foldability of the cover sheet 102 in the flexible display device is satisfied. The second bending regions 101a respectively correspond to the first bending regions 102a. The flexible display panel 101 further includes first non-bending regions 102b. Two first non-bending regions 102b are disposed on two opposite sides of each of the first bending regions 102a respectively. As shown in FIG. 1, the cover sheet 102 has a first bending region 102a. Two first non-bending regions 102b are disposed on two opposite sides of the first bending region 102a respectively.

A photoresponsive polymer layer 1021 is disposed in the first bending region 102a of the cover sheet 102. Material composition of the photoresponsive polymer layer 1021 includes a photoresponsive polymer. The photoresponsive polymer is either a rigid polymer under a first illuminating condition or a flexible polymer under a second illuminating condition. The photoresponsive polymer is a rigid polymer under the first illuminating condition, so that the photoresponsive polymer layer 1021 under the first illuminating condition has good mechanical performance, such as hardness and strength, under the first illuminating condition, preventing the cover sheet 102 from being scratched or breaking. The photoresponsive polymer is a flexible polymer under the second illuminating condition, so that the photoresponsive polymer layer 1021 under the second illuminating condition has good flexibility, such as good tensile performance or bendable performance, and thus satisfies the demand for bendability of the flexible display device.

When the flexible display device is in a bending state, the photoresponsive polymer layer 1021 in the first bending region 102a has good flexibility under the second illuminating condition, causing the cover sheet 102 in the first bending region 102a to be bent well. When the flexible display device is in an opened state, the photoresponsive polymer layer 1021 in the first bending region 102a has good mechanical performance under the first illuminating condition, preventing the cover sheet 102 in the first bending region 102a from being scratched or breaking. Thus, protection is achieved.

In the present embodiment, the photoresponsive polymer layer 1021 extends from the first bending region 102a to the first non-bending regions 102b, so that the cover sheet 102 has good mechanical performance under the first illuminating condition and has good flexibility under the second illuminating condition. Further, the cover sheet 102 is adaptive to the flexible display device.

Further, the cover sheet 102 includes a hard layer 1022 disposed in the first non-bending regions 102b and on the photoresponsive polymer layer 1021, so that the hardness of the surface of the cover sheet 102 in the first non-bending regions 102b is improved, and the cover sheet 102 is further prevented from being damaged or breaking under external force. Specifically, the hard layer 1022 is disposed on a surface of the photoresponsive polymer layer 1021, away from the flexible display panel 101. The hard layer 1022 can be made of at least one of silicon oxide, silicon nitride, alumina, calcium fluoride, magnesium fluoride, aluminum fluoride, and barium fluoride.

Further, a refractive index of the hard layer 1022 is greater than that of air, and a refractive index of the photoresponsive polymer layer 1021 under the first illuminating condition is greater than that of the hard layer 1022, so that light emitted from the organic light-emitting diodes passes through a medium layer whose a refractive index is decreased gradually to improve light-emitting efficiency of the flexible display device. For example, the hard layer 1022 can be made of at least one of calcium fluoride, magnesium fluoride, aluminum fluoride, and barium fluoride.

Further, the cover sheet 102 includes an anti-reflective layer 1023 disposed in the first bending region 102a and on a surface of the photoresponsive polymer layer 1021 away from the flexible display panel 101. A refractive index of the anti-reflective layer 1023 is greater than that of air, and a refractive index of the photoresponsive polymer layer 1021 under the first illuminating condition is greater than that of the anti-reflective layer 1023. The anti-reflective layer 1023 is a transparent organic layer.

In the present embodiment, the first illuminating condition includes a surrounding light illumination and/or an ultraviolet illumination. The ultraviolet light can also come from the surrounding light or can be provided by the flexible display panel 101. The surrounding light consists of colored light with different wavelengths. The ratios of the colored light with different wavelengths are different, causing intensity of red light, blue light, green light, and other colored light in the surrounding light to be lower. For example, intensity of red light in the surrounding light is lower than that of pure red light. A wavelength of ultraviolet light can be set between 100 and 380 nanometers. For example, the wavelength of ultraviolet light is 360 nanometers. When the flexible display device is in an opened state, the photoresponsive polymer becomes rigid under the surrounding light illumination, causing the cover sheet 102 in the first bending region 102a to have good mechanical performance. Probably, the flexible display device becomes rigid under the ultraviolet illumination with certain intensity.

In the present embodiment, the second illuminating condition includes one of a red-light illumination, a blue-light illumination, a green-light illumination, and a lightless illumination. Intensity of the red-light illumination, the blue-light illumination, and the green-light illumination is greater than that of red light, blue light, and green light of the surrounding light illumination. The red-light illumination, the blue-light illumination, and the green-light illumination can be provided by the flexible display panel 101. For example, when the flexible display device is an inward-bent flexible display device, blue organic light-emitting diodes in the flexible display panel emit blue light, and both red organic light-emitting diodes and green organic light-emitting diodes do not emit light in order to display pure blue pictures, so that the cover sheet 102 in the first bending region 102a has good flexibility. Probably, when the flexible display device is in an inward-bent state, the photoresponsive polymer layer 1021 is under a lightless illumination, and the cover sheet in the first bending region 102a has good flexibility.

When the flexible display device is in an opened state, the photoresponsive polymer layer 1021 in the first bending region 102a has good mechanical performance under the surrounding light illumination or the ultraviolet illumination. The flexible display panel 101 emits blue light whose intensity is greater than the blue light in the surrounding light, the flexible display panel 101 emits red light whose intensity is greater than the red light in the surrounding light, or the flexible display panel 101 emits green light whose intensity is greater than the green light in the surrounding light, causing the photoresponsive polymer layer 1021 to receive one of intensity of blue light, red light, and green light from the flexible display panel 101, which is greater than that of red light, blue light, and green light in the surrounding light. In response to one of blue light, red light, and green light, the photoresponsive polymer becomes flexible. It is beneficial for the stretch of the cover sheet 102 to be suited to the flexible display device in the course of being bent. After the flexible display device is bent, the photoresponsive polymer layer 1021 remains good flexibility under the lightless illumination.

In the present embodiment, the photoresponsive polymer is selected from a photoresponsive isomeric polymer, that is, the photoresponsive polymer interacts with light to be isomeric. The photoresponsive polymer is selected from an azo polymer or an azo derivative polymer. The azo polymer includes an aromatic azo polymer, such as an azobenzene polymer, etc. Because the aromatic azo polymer is of an aromatic structure, the photoresponsive polymer has better rigidness under an illuminating condition. Thus, the rigidness of the photoresponsive polymer under an illuminating condition is further improved. The azo derivative polymer includes a polyether aromatic azo polymer, etc.

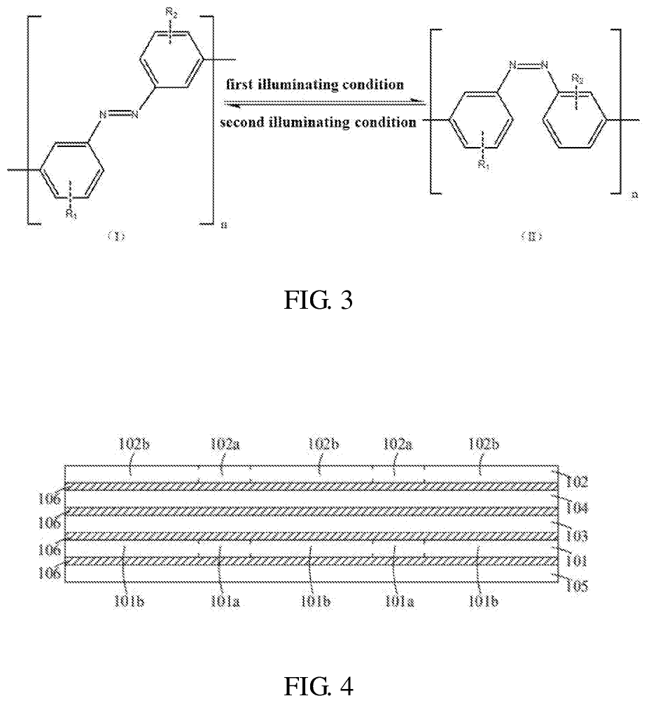

Please refer to FIG. 3, which is a schematic diagram of transition of a photoresponsive polymer under a first illuminating condition and under a second illuminating condition. A photoresponsive polymer (I) becomes a photoresponsive polymer (II) under the first illuminating condition. The photoresponsive polymer (II) becomes the photoresponsive polymer (I) under the second illuminating condition. Both R1 and R2 are substituents, which can be alkyl, phenyl, amido, or other substituents. The selection of the substituents depends, on the one hand, on a photoresponsive transitional condition of the photoresponsive polymer, and depends, on the other hand, on the demand for the flexibility and the rigidness of the photoresponsive polymer. The photoresponsive polymer (I) is a trans isomeric azo polymer and has a smaller space resistance, so that the photoresponsive polymer (I) has good flexibility, and the photoresponsive polymer layer 1021 under the second illuminating condition has good flexibility. The photoresponsive polymer (II) is a cis isomeric azo polymer and has a greater space resistance, so that the photoresponsive polymer (II) is a rigid polymer, and the photoresponsive polymer layer 1021 under the first illuminating condition has good mechanical performance.

The photoresponsive polymer has a transitional relaxation time of less than 1 second, so that it can finish transition from the rigid polymer to the flexible polymer or transition from the flexible polymer to the rigid polymer in a shorter time. Thus, the demand for the flexibility and the rigidness of the cover sheet 102 is satisfied when the flexible display device changes between an inward-bent closed state and an opened state. Further, the transitional relaxation time of the photoresponsive polymer is less than 0.5 second, so that the photoresponsive polymer can finish transition from the rigid polymer to the flexible polymer or transition from the flexible polymer to the rigid polymer in an even shorter time. Thus, the time required by a change of mechanical performance is further shortened when the flexible display device changes between an inward-bent closed state and an opened state. Because light energy required by the photoresponsive polymer changing between rigidity and flexibility is smaller, light energy with a milliwatt level can drive the photoresponsive polymer to generate rigid transition.

It needs to be stated that the photoresponsive polymer is a transparent material, so that the cover sheet 102 made of the photoresponsive polymer also has good transparency.

A touch layer 103 receives a touch signal to control the flexible display panel 101 to display image information. The touch layer 103 is disposed between the cover sheet 102 and the flexible display panel 101. Specifically, the touch layer 103 is stuck on a light-emitting surface of the flexible display panel 101 through an optical clear adhesive 106. The touch layer 103 can include a capacitive touch assembly. The touch layer 103 can include a resistance touch assembly. The touch layer 103 can also include an optical touch assembly, etc.

The polarizing sheet 104 can deflect light, causing light with a specific vibrational direction to pass and causing light with other vibrational directions not to pass. The polarizing sheet 104 is disposed between the touch layer 103 and the cover sheet 102. Specifically, the polarizing sheet 104 is stuck on one side of the touch layer 103, away from the flexible display panel 101, through the optical clear adhesive 106. The polarizing sheet 104 can a circular-polarizing sheet, so that the reflection of the surrounding light is reduced and the display effect of the flexible display device is improved.

The rear cover sheet 105 can protect the flexible display panel 101. The rear cover sheet 105 is stuck on one side of the flexible display panel 101, away from the touch layer 103, through the optical clear adhesive 106.

In an embodiment of the present disclosure, a cover sheet of a flexible display device has at least one first bending region and includes a photoresponsive polymer layer disposed in the at least one first bending region of the cover sheet. Material composition of the photoresponsive polymer layer includes a photoresponsive polymer. The photoresponsive polymer is either a rigid polymer under a first illuminating condition or a flexible polymer under a second illuminating condition, causing the cover sheet corresponding to a bending region of the flexible display device to have good flexibility when the flexible display device is bent, and to have good mechanical performance when the flexible display device is opened. Thus, protection is achieved.

Please refer to FIG. 4, which is a schematic structural diagram of a flexible display device according to a second embodiment of the present disclosure. Basically, the flexible display device as shown in FIG. 4 is similar to the flexible display device as shown in FIG. 1. There exists a difference in that the flexible display device has several bending regions 1. Correspondingly, the cover sheet 102 has several first bending regions 102a. The flexible display panel 101 has several second non-bending regions 101b, causing the flexible display device to have even better flexibility.

The above descriptions of the embodiments are merely for understanding the technical solution and the core ideas of the present disclosure. It should be understood that a person skilled in the art may still make modifications to the technical solution described in the above embodiments, or equivalently replace a part of technical features therein. However, the modifications or replacement do not make the nature of corresponding technical solutions depart from the scope of the technical solution described in the embodiments of the present disclosure.

What is claimed is:

1. A cover sheet having at least one first bending region, the cover sheet comprising:
a photoresponsive polymer layer disposed in the at least one first bending region of the cover sheet, wherein material composition of the photoresponsive polymer layer comprises a photoresponsive polymer, and wherein the photoresponsive polymer is either a rigid polymer under a first illuminating condition or a flexible polymer under a second illuminating condition.

2. The cover sheet of claim 1, wherein two first non-bending regions are disposed on two opposite sides of each of the at least one first bending region respectively.

3. The cover sheet of claim 2, wherein the photoresponsive polymer layer extends from the at least one first bending region to the first non-bending regions.

4. The cover sheet of claim 3, further comprising: a hard layer disposed in the non-bending regions and on a surface of the photoresponsive polymer layer.

5. The cover sheet of claim 1, wherein the first illuminating condition comprises a surrounding light illumination and/or an ultraviolet illumination; and
wherein the second illuminating condition comprises one of a red-light illumination, a blue-light illumination, a green-light illumination, and a lightless illumination, and intensity of the red-light illumination, the blue-light illumination, and the green-light illumination is greater than that of red light, blue light, and green light of the surrounding light illumination.

6. The cover sheet of claim 1, wherein the photoresponsive polymer is selected from an azo polymer or an azo derivative polymer.

7. The cover sheet of claim 6, wherein the photoresponsive polymer is an aromatic azo polymer.

8. The cover sheet of claim 1, wherein the photoresponsive polymer has a transitional relaxation time of less than 1 second.

9. The cover sheet of claim 8, wherein the transitional relaxation time of the photoresponsive polymer is less than 0.5 second.

10. A flexible display device, comprising a cover sheet and a flexible display panel, wherein the cover sheet is disposed on a light-emitting side of the flexible display panel;
wherein the cover sheet has at least one first bending region and comprises a photoresponsive polymer layer disposed in the at least one first bending region of the cover sheet, material composition of the photoresponsive polymer layer comprises a photoresponsive polymer, and the photoresponsive polymer is either a rigid polymer under a first illuminating condition or a flexible polymer under a second illuminating condition; and
wherein the flexible display panel has at least one second bending region respectively corresponding to the at least one first bending region.

11. The flexible display device of claim 10, wherein two first non-bending regions are disposed on two opposite sides of each of the at least one first bending region respectively.

12. The flexible display device of claim 11, wherein the photoresponsive polymer layer extends from the at least one first bending region to the first non-bending regions.

13. The flexible display device of claim 12, the cover sheet further comprises a hard layer disposed in the non-bending regions and on a surface of the photoresponsive polymer layer.

14. The flexible display device of claim 10, wherein the first illuminating condition comprises a surrounding light illumination and/or an ultraviolet illumination; and
wherein the second illuminating condition comprises one of a red-light illumination, a blue-light illumination, a green-light illumination, and a lightless illumination, and intensity of the red-light illumination, the blue-light illumination, and the green-light illumination is greater than that of red light, blue light, and green light of the surrounding light illumination.

15. The flexible display device of claim 14, wherein the red-light illumination, the blue-light illumination, and the green-light illumination are provided by the flexible display panel.

16. The flexible display device of claim 10, wherein the photoresponsive polymer is selected from an azo polymer or an azo derivative polymer.

17. The flexible display device of claim 16, wherein the photoresponsive polymer is an aromatic azo polymer.

18. The flexible display device of claim 10, wherein the photoresponsive polymer has a transitional relaxation time of less than 1 second.

19. The flexible display device of claim 10, further comprising: a touch layer disposed between the cover sheet and the flexible display panel.
